(19) United States
(12) Patent Application Publication
(10) Pub. No.: US 2025/0208452 A1
(43) Pub. Date: Jun. 26, 2025

(54) APPARATUS FOR TRANSFERRING DISPLAY PANEL

(71) Applicant: Samsung Display Co., LTD., Yongin-si (KR)

(72) Inventors: Byung Su KIM, Yongin-si (KR); Suk Ju KANG, Yongin-si (KR); Seung Min HONG, Yongin-si (KR)

(73) Assignee: Samsung Display Co., LTD., Yongin-si (KR)

(21) Appl. No.: 18/989,500

(22) Filed: Dec. 20, 2024

(30) Foreign Application Priority Data
Dec. 22, 2023 (KR) 10-2023-0189539
Aug. 22, 2024 (KR) 10-2024-0112676

(51) Int. Cl. G02F 1/13; H10K 59/12

(52) U.S. Cl. CPC G02F 1/1303; H10K 59/1201

(57) ABSTRACT

An apparatus for transferring a display device includes a frame, a carrier disposed on the frame to be movable in a first direction, an adsorption plate disposed on the carrier to support the display panel, a first manifold formed at the frame to be movable in a second direction, including a plurality of first holes, and a second manifold formed at the adsorption plate to face the first manifold, including a plurality of second holes, wherein the first manifold may be driven in one of a docking mode in which the first manifold is in contact with the second manifold such that the plurality of first holes are connected to the plurality of second holes and a standby mode in which the first manifold is spaced apart from the second manifold such that the plurality of first holes are separated from the plurality of second holes.

### CROSS-REFERENCE TO RELATED APPLICATION(S)

This application claims priority to and benefits of Korean Patent Application 10-2023-0189539, filed on Dec. 22, 2023, and Korean Patent Application 10-2024-0112676, filed on Aug. 22, 2024, under 35 U.S.C. § 119, the entire contents of which are incorporated herein by reference.

### BACKGROUND

### 1. Technical Field

Embodiments relate to an apparatus for transferring a display panel.

### 2. Description of the Related Art

With the development of information technologies, the importance of a display device which is a connection medium between a user and information increases. Accordingly, display devices such as a liquid crystal display device and an organic light emitting display device are increasingly used.

Various processes are performed in a process of manufacturing a display device. These processes may be performed at different positions. In order to safely transfer a display panel being manufactured to another position without physical and chemical influence, the display panel is generally fixed on a movable carrier and then transferred through the carrier. In order to precisely move the display panel, a clamper or a vacuum pump, which is used to prevent separation of the display panel, may be formed in the carrier.

### SUMMARY

Embodiments provide an apparatus for transferring a display panel, which can precisely transfer the display panel without damage.

However, embodiments are not limited to those set forth herein. The above and other embodiments will become more apparent to one of ordinary skill in the art to which the disclosure pertains by referencing the detailed description of the disclosure given below.

According to an embodiment, there is provided an apparatus for transferring a display panel, the apparatus including: a frame; a carrier disposed on the frame to be movable in a first direction and an opposite direction of the first direction; an adsorption plate disposed on the carrier to support the display panel; a first manifold including a plurality of first holes, the first manifold being formed at the frame to be movable in a second direction intersecting the first direction and an opposite direction of the second direction; and a second manifold including a plurality of second holes, the second manifold being formed at the adsorption plate to face the first manifold, wherein the first manifold is driven in a docking mode and a standby mode, in the docking mode, the first manifold is in contact with the second manifold such that the plurality of first holes are connected to the plurality of second holes, and in the standby mode, the first manifold is spaced apart from the second manifold such that the plurality of first holes are separated from the plurality of second holes.

In an embodiment, the adsorption plate may include: a plurality of adsorption holes connected to the plurality of second holes; and a plurality of adsorption paths connecting the plurality of adsorption holes to each other.

In an embodiment, the plurality of adsorption holes may include: a plurality of first adsorption holes adjacent to a center portion of the adsorption plate; and a plurality of second adsorption holes spaced farther from the center portion of the adsorption plate than the plurality of first adsorption holes. Each adsorption path may include: a first adsorption path connecting the plurality of first adsorption holes to each other; and a second adsorption path connecting the plurality of second adsorption holes to each other.

In an embodiment, the first adsorption path may be connected to one of the plurality of second holes, and the second adsorption path may be connected to another one of the plurality of second holes.

In an embodiment, at least one of the first and second adsorption paths may have an open-loop shape.

In an embodiment, the plurality of adsorption holes may penetrate the adsorption plate in a third direction intersecting the first and second directions.

In an embodiment, the apparatus may further include at least one vacuum chamber formed at a surface of the adsorption plate, which is not in contact with the display panel, the at least one vacuum chamber being connected to some of the plurality of adsorption holes.

In an embodiment, the apparatus may further include an air suction member connected to the plurality of first holes and the plurality of second holes to suck air between the display panel and the adsorption plate in case that the first manifold is driven in the docking mode.

In an embodiment, the first manifold may further include a plurality of first air injection holes, and the second manifold may further include a plurality of second air injection holes. In case that the first manifold is driven in the docking mode, the plurality of first air injection holes may be connected to the plurality of second air injection holes, respectively.

In an embodiment, a number of the plurality of first holes and a number of the plurality of first air injection holes may be equal to each other, and a number of the plurality of second holes and a number of the plurality of second air injection holes may be equal to each other.

In an embodiment, at least one of the first manifold and the second manifold may further include an impact absorbing member surrounding a circumference of each of the plurality of first air injection holes or the plurality of second air injection holes disposed on a surface at which the first manifold and the second manifold face each other. In case that the first manifold is driven in the docking mode, the impact absorbing member may seal one of the plurality of first holes and one of the plurality of second holes, which are connected to each other.

In an embodiment, the apparatus may further include an air injection member connected to one of the plurality of first air injection holes and one of the plurality of second air injection holes, which are connected to each other, to inject air into the second manifold in case that the first manifold is driven in the docking mode.

In an embodiment, the second manifold may further include: a valve member movable between a first position at which the valve member interrupts a flow of air into one of the plurality of second holes and a second position at which the value member allows a flow of air into one of the plurality of second holes; an elastic member disposed between an inner surface of the second manifold and the valve member to provide an elastic force to the valve member; and a tube having an end portion connected to one of the plurality of second air injection holes and another end portion connected to an empty space between the second manifold and the valve member.

In an embodiment, in case that a flow of air does not exist or in case that a flow of air from one of the plurality of first holes to one of the plurality of second holes occurs, the valve member may move to the first position by the elastic force with which the elastic member pressurizes the valve member.

In an embodiment, in case that a flow of air from one of the plurality of second holes to one of the plurality of first holes occurs, the valve member may move to the second position by an air pressure that is higher than the elastic force.

In an embodiment, in case that the valve member moves to the second position, the adsorption plate may adsorb the display panel by inducing a vacuum condition in a space between the display panel and the adsorption plate.

In an embodiment, in case that air is introduced into one of the plurality of second air injection holes, the air introduced into the one of the plurality of second air injection holes may be induced to the empty space between the second manifold and the valve member while moving along the tube. The valve member may move to the second position by air pressure applied to the empty space between the second manifold and the valve member and being higher than the elastic force.

In an embodiment, in case that the valve member moves to the second position, an adsorption condition of the display panel and the adsorption plate may be cancelled by the air supplied to a space between the display panel and the adsorption plate.

In an embodiment, at least one of the first manifold and the second manifold may further include an impact absorbing member surrounding a circumference of each of the plurality of first holes or the plurality of second holes disposed on a surface at which the first manifold and the second manifold face each other. In case that the first manifold is driven in the docking mode, the impact absorbing member may seal one of the plurality of first holes and one of the plurality of second holes, which are connected to each other.

In an embodiment, the apparatus may further include a driving member formed at the first manifold to provide the first manifold with a driving force with which the first manifold moves in the second direction and the opposite direction of the second direction.

### BRIEF DESCRIPTION OF THE DRAWINGS

The above and other features of the invention will now be described more fully hereinafter with reference to the accompanying drawings; however, they may be embodied in different forms and should not be construed as limited to the embodiments set forth herein. Rather, these embodiments are provided so that this invention will be thorough and complete, and will fully convey the scope of the example embodiments to those skilled in the art.

In the drawing figures, dimensions may be exaggerated for clarity of illustration. It will be understood that in case that an element is referred to as being “between” two elements, it can be the only element between the two elements, or one or more intervening elements may also be present. Like reference numerals refer to like elements throughout.

FIG. 1 is a schematic perspective view illustrating an embodiment an apparatus for transferring a display panel.

FIG. 2 is a schematic plan view illustrating an embodiment of a portion of the apparatus shown in FIG. 1.

FIG. 3 is a schematic sectional view illustrating an embodiment taken along line I-I′ shown in FIG. 2.

FIG. 4 is a schematic front view illustrating a first manifold viewed from the front.

FIG. 5 is a schematic sectional view illustrating an embodiment taken along line II-II′ shown in FIG. 4.

FIG. 6 is a schematic sectional view illustrating an embodiment taken along line III-III′ shown in FIG. 4.

FIG. 7 is a schematic front view illustrating a second manifold viewed from the front.

FIG. 8 is a schematic sectional view illustrating an embodiment taken along line IV-IV′ shown in FIG. 7.

FIG. 9 is a schematic sectional view illustrating an embodiment taken along line V-V′ shown in FIG. 7.

FIG. 10 is a schematic sectional view illustrating embodiments taken along line A-A′ shown in FIG. 4 and line B-B′ shown in FIG. 7 in case that the first manifold and the second manifold are in contact with each other.

FIG. 11 is a schematic view illustrating an embodiment of the second manifold in case that the first manifold is in a standby mode.

FIG. 12 is a schematic view illustrating an operation example of the second manifold in case that the first manifold is driven in a docking mode.

FIG. 13 is a schematic view illustrating another operation example of the second manifold in case that the first manifold is driven in the docking mode.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

For example, the embodiments are described here with reference to schematic diagrams of embodiments (and an intermediate structure), so that changes in a shape as shown due to, for example, manufacturing technology and/or a tolerance may be expected. Therefore, the embodiments shall not be limited to the specific shapes of a region shown here, but include shape deviations caused by, for example, the manufacturing technology. The regions shown in the drawings are schematic in nature, and the shapes thereof do not represent the actual shapes of the regions of the device, and do not limit the scope of the invention.

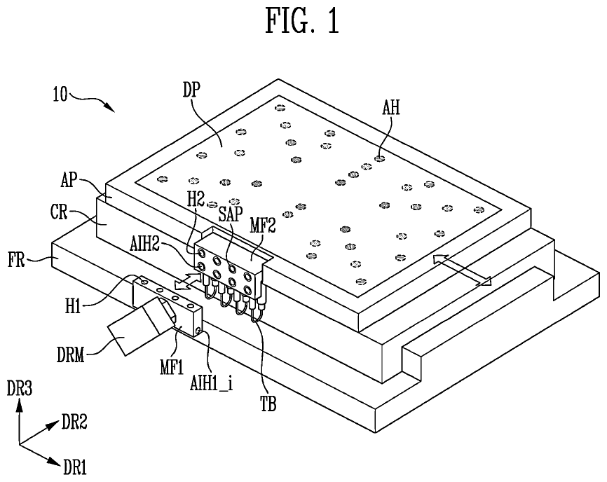

FIG. 1 is a schematic perspective view illustrating an embodiment an apparatus for transferring a display panel.

Referring to FIG. 1, the apparatus 10 in accordance with the embodiment may include a frame FR, a carrier CR, an adsorption plate AP, a first manifold MF1, a second manifold MF2, and a driving member DRM.

The frame FR may be a component forming a basic frame of the apparatus 10, and may function to stably support other components. The frame FR may extend in a first direction DR1, and provide a space in which the carrier CR is slidable in the first direction DR1 and the opposite direction of the first direction DR1 on the frame FR. In embodiments, a linear motion (LM) guide may be installed (or formed) in the frame FR, and the carrier CR may be slidable along a direction in which the LM guide extends on the frame FR.

The carrier CR may be disposed to be movable in the first direction DR1 and the opposite direction of the first direction DR1 on the frame FR. As described above, the carrier CR may be slidable on a movement assistance means such as the LM guide installed (or formed) in the frame FR, and the adsorption plate AP disposed on the carrier CR may also move together with the carrier CR according to such sliding.

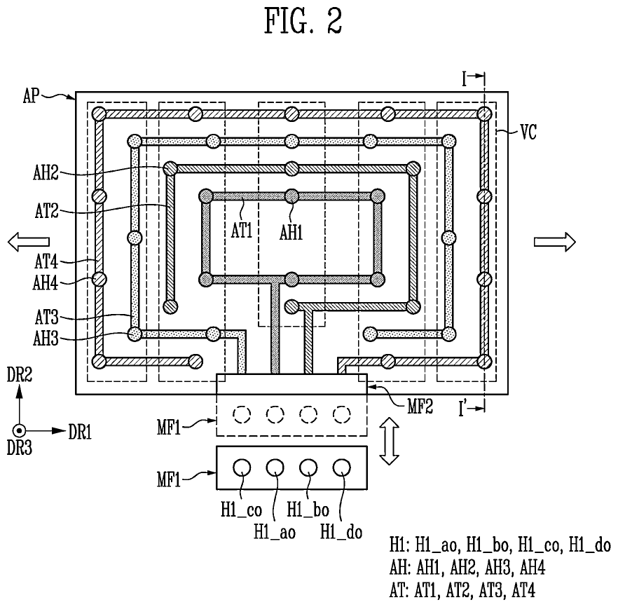

The adsorption plate AP may be disposed on the carrier CR to support a display panel DP. The adsorption plate AP may be fixed to the carrier CR not to move on the carrier CR, and accordingly, the adsorption plate AP may also move together with the carrier CR in case that the carrier CR moves. A specific configuration of the adsorption plate AP will be described in detail below with reference to FIG. 2.

The first manifold MF1 may include first holes H1, and be installed (or formed) at the frame FR to be movable in a second direction DR2 intersecting the first direction DR1 and the opposite direction of the second direction DR2. In embodiments, the first manifold MF1 may be installed (or formed) at a height overlapping the adsorption plate AP in a horizontal direction. The term “horizontal direction” means a direction in which a plane formed by the first direction DR1 and the second direction DR2 extends.

The second manifold MF2 may include second holes H2, and be installed (or formed) at the adsorption plate AP to face the first manifold MF1. In embodiments, the second manifold MF2 may be installed (or formed) at a height overlapping the first manifold MF1 in the horizontal direction. For example, the second manifold MF2 may be installed (or formed) at a position at which the second holes H2 respectively overlap the first holes H1, in a one-to-one correspondence.

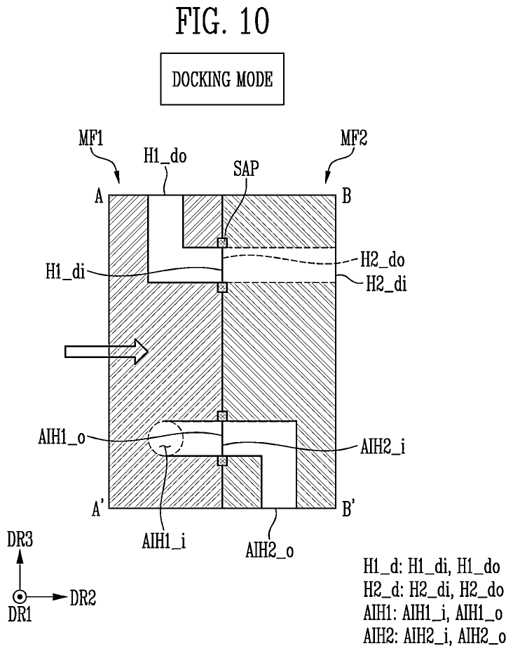

In embodiments, the first manifold MF1 may be driven in a docking mode and a standby mode. For example, in the docking mode, the first manifold MF1 may be contact with the second manifold MF2 such that the first holes H1 are respectively connected to the second holes H2. In the standby mode, the first manifold MF1 may be spaced apart from the second manifold MF2 such that the first holes H1 are separated from the second holes H2. A state in which the first manifold MF1 is driven in the docking mode or the standby mode will be described in detail below with reference to FIGS. 10 to 13.

The driving member DRM may be installed (or formed) at the first manifold MF1, and provide the first manifold MF1 with a driving force for allowing the first manifold MF1 to move in the second direction DR2 and the opposite direction of the second direction DR2.

Hereinafter, the adsorption plate AP will be described in more detail with reference to FIG. 2.

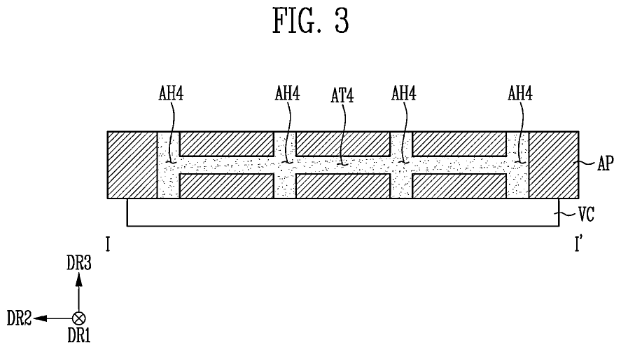

FIG. 2 is a schematic plan view illustrating an embodiment of a portion of the apparatus shown in FIG. 1. FIG. 3 is a schematic sectional view illustrating an embodiment taken along line I-I′ shown in FIG. 2.

Referring to FIG. 2, the adsorption plate AP may include adsorption holes AH and adsorption paths AT.

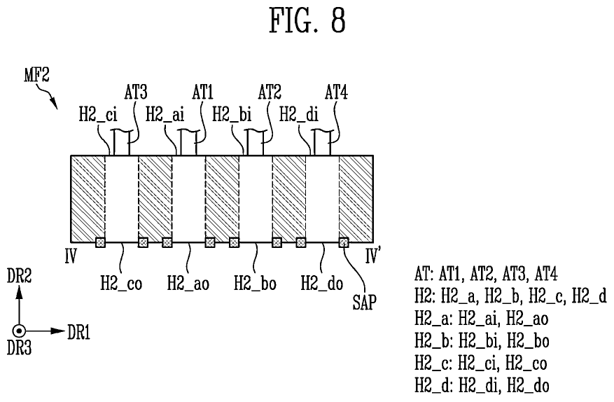

The adsorption holes AH may be connected to the second holes H2 through the adsorption paths AT. Further, a coupling relationship between the second holes H2 and the adsorption paths AT will be described later with reference to FIG. 8.

In embodiments, the adsorption holes AH may include first adsorption holes AH1 adjacent to a center portion of the adsorption plate AP and second adsorption holes AH2 spaced farther from the center portion of the adsorption plate AP than the first adsorption holes AH1, but embodiments are not limited thereto. For example, the adsorption holes AH may further include third adsorption holes AH3 spaced farther from the center portion of the adsorption plate AP than the second adsorption holes AH2 and fourth adsorption holes AH4 spaced farther from the center portion of the adsorption plate AP than the third adsorption holes AH3. Each of the first to fourth adsorption holes AH1 to AH4 may be sequentially arranged along a radial direction with respect to the center portion of the adsorption plate AP.

The adsorption paths AT may connect the adsorption holes AH to each other. In embodiments, the adsorption paths AT may include a first adsorption path AT1 connecting the first adsorption holes AH1 to each other and a second adsorption path AT2 connecting the second adsorption holes AH2 to each other, but embodiments are not limited thereto. For example, as shown in the drawing, the adsorption paths AT may further include a third adsorption path AT3 connecting the third adsorption holes AH3 to each other and a fourth adsorption path AT4 connecting the fourth adsorption holes AH4 to each other. The second adsorption path AT2 may surround the first adsorption path AT1, the third adsorption path AT3 may surround the second adsorption path AT2, and the fourth adsorption path AT4 may surround the third adsorption path AT3.

Referring to FIGS. 1 and 2 together, the first adsorption path AT1 may be connected to any one of the second holes H2, and the second adsorption path AT2 may be connected to another one of the second holes H2. For example, the third adsorption path AT3 may be connected to still another one of the second holes H2, and the fourth adsorption path AT4 may be connected to any one second hole H2 which is not connected to the first to third adsorption paths AT1 to AT3 among the second holes H2. Such a coupling relationship between the second holes H2 and the adsorption path AT will be described in more detail below with reference to FIG. 8.

For example, the first to fourth adsorption paths AT1 to AT4 may not overlap each other with respect to a vertical direction. The term “vertical direction” means a third direction DR3 as a thickness direction of the carrier CR, the adsorption plate AP, and the display panel DP. In embodiments, at least one of the first to fourth adsorption paths AT1 to AT4 may have an open-loop shape. For example, as shown in FIG. 2, the first adsorption path AT1 may have a closed-loop shape, and the other second to fourth adsorption paths AT2 to AT4 except the first adsorption path AT1 may have an open-loop shape not to overlap each other in the vertical direction.

For example, the adsorption holes AH may penetrate the adsorption plate AP in the third direction DR3, i.e., the vertical direction, intersecting the first and second directions DR1 and DR2.

FIG. 3 illustrates only the fourth adsorption holes AH4 and the fourth adsorption path AT4 among the first to fourth adsorption holes AH1 to AH4 and the first to fourth adsorption paths AT1 to AT4. However, the first to third adsorption holes AH1 to AH3 and the first to third adsorption paths AT1 to AT3 may also be configured identically to the fourth adsorption holes AH4 and the fourth adsorption path AT4, and therefore, redundant descriptions will be omitted.

Referring to FIG. 3, the fourth adsorption holes AH4 may penetrate the adsorption plate AP in the third direction DR3. The fourth adsorption holes AH4 may be connected to each other through the fourth adsorption path AT4.

Referring to FIGS. 2 and 3 together, at least one vacuum chamber VC may be installed (or formed) at a surface of the adsorption plate AP, which is not in contact with the display panel DP. In FIG. 2, it is illustrated that five vacuum chambers extending in the second direction DR2 are installed (or formed) at the surface of the adsorption plate AP. However, embodiments are not limited thereto. For example, the vacuum chamber VC may extend in the first direction DR1, and the number and shape of vacuum chambers VC may be freely selected on a plane formed by the first direction DR1 and the second direction DR2. For example, four vacuum chambers VC may be installed (or formed) at the adsorption plate AP, like the number of the first to fourth adsorption paths AT1 to AT4. Each of the vacuum chambers VC may overlap each of the first to fourth adsorption paths AT1 to AT4 in the vertical direction.

Since an internal space of the vacuum chamber VC is maintained in a vacuum state, the vacuum chamber VC may function to allow a space between the display panel DP and the adsorption plate AP to be maintained in the vacuum state. This is related to a case where the first manifold MF1 is driven in the docking mode. Therefore, this will be described in more detail below with reference to FIGS. 10 to 13.

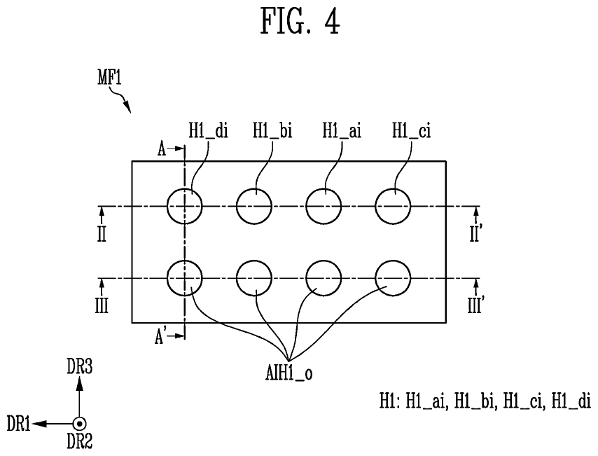

Hereinafter, configurations of the first manifold MF1 and the second manifold MF2 and a coupling relationship between the first manifold MF1 and the second manifold MF2 will be described in detail with reference to FIGS. 4 to 9.

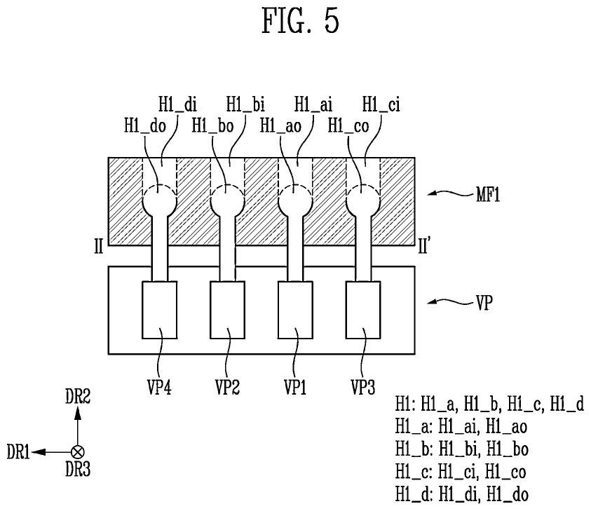

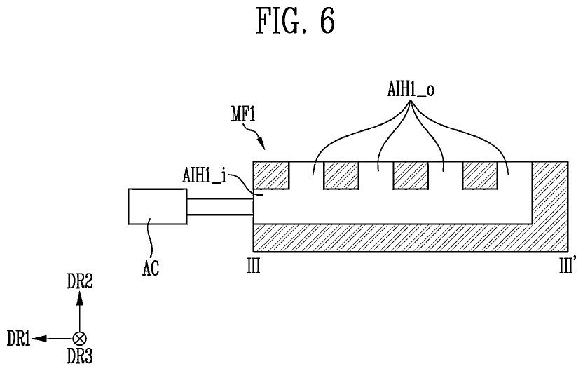

FIG. 4 is a schematic front view illustrating the first manifold viewed from the front. FIG. 5 is a schematic sectional view illustrating an embodiment taken along line II-II′ shown in FIG. 4. FIG. 6 is a schematic sectional view illustrating an embodiment taken along line III-III′ shown in FIG. 4.

Referring to FIGS. 4 to 6, the first manifold MF1 may include first holes H1 and first air injection holes AIH1.

The first holes H1 may include a (1_a)th sub-hole H1_a, a (1_b)th sub-hole H1_b, a (1_c)th sub-hole H1_c, and a (1_d)th sub-hole H1_d. The (1_a)th to (1_d)th sub-holes H1_a to H1_d may be arranged along the first direction DR1.

The first holes H1 may be respectively connected to the second holes H2 in case that the first manifold MF1 is driven in the docking mode.

The first air injection holes AIH1 may be spaced apart from the first holes H1 in the third direction DR3, and be arranged side by side along the first direction DR1, like the first holes H1.

In embodiments, a number of the first holes H1 and a number of the first air injection holes AIH1 may be equal to each other. In the drawings, it is described that four first holes H1 and four first air injection holes AIH1 are formed. However, embodiments are not limited thereto. The number of the first holes H1 and the number of the first air injection holes AIH1 may be equal to the number of the second holes H2 formed in the second manifold MF2 and the number of the adsorption paths AT formed in the adsorption plate AP.

The first air injection holes AIH1 may be respectively connected to second air injection holes AIH2 in case that the first manifold MF1 is driven in the docking mode.

FIG. 5 illustrates an embodiment of the first manifold MF1, taken along the line II-II′ shown in FIG. 4, and simultaneously illustrates air suction members VP connected to the first holes H1.

Referring to FIG. 5, an air suction member VP may be connected to the first holes H1. In embodiments, the air suction member VP may include first to fourth air suction members VP1 to VP4 respectively connected to the (1_a)th to (1_d)th sub-holes H1_a to H1_d, but embodiments are not limited thereto. For example, the air suction member VP may be configured as one air suction member to be integrally connected to the (1_a)th to (1_d)th sub-holes H1_a to H1_d.

The first air suction member VP1 may be connected to a side of an outlet H1_ao of the (1_a)th sub-hole H1_a. The second air suction member VP2 may be connected to a side of an outlet H1_bo of the (1_b)th sub-hole H1_b. The third air suction member VP3 may be connected to a side of an outlet H1_co of the (1_c)th sub-hole H1_c. The fourth air suction member VP4 may be connected to a side of an outlet H1_do of the (1_d)th sub-hole H1_d.

FIG. 6 illustrates an embodiment of the first manifold MF1, taken along the line III-III′ shown in FIG. 4, and simultaneously illustrates an air injection member AC connected to a first air injection hole AIH1.

Referring to FIG. 6, the first manifold MF1 may include a first air injection hole AIH1. An air injection member AC may be connected to the first air injection hole AIH1. The air injection hole AIH1 may include one inlet AIH1_i and outlets AIH1_o connected to the inlet AIH1_i, but embodiments are not limited thereto. For example, the inlet AIH1_i of the first air injection hole AIH1 may be configured with several inlets to be respectively connected to the outlets AIH1_o. However, for convenience of description, a case where one inlet AIH1_i of the air injection hole AIH1 is provided will be mainly described hereinbelow. For example, one air injection member AC connected to one inlet AIH1_i of the first air injection hole AIH1 is illustrated in the drawing, but embodiments are not limited thereto. For example, the air injection member AC may be configured (or formed) to have a number equal to a number of the outlets AIH1_o of the first air injection hole AIH1, like that the air suction member VP includes the first to fourth air suction members VP1 to VP4 to be respectively connected to the (1_a)th to (1_d)th sub-holes H1_a to H1_d.

The number of the outlets AIH1_o of the first air injection hole AIH1 may be equal to the number of the first holes H1. Each of the outlets AIH1_o of the first air injection hole AIH1 may be connected to each of the second air injection holes AIH2, which corresponds thereto, in case that the first manifold MF1 is driven in the docking mode.

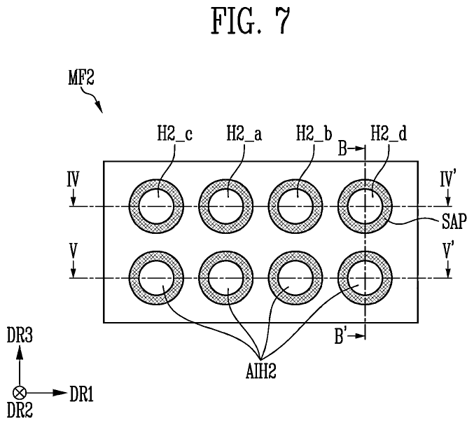

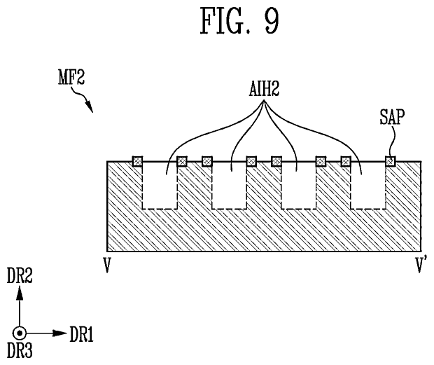

FIG. 7 is a schematic front view illustrating the second manifold viewed from the front. FIG. 8 is a schematic sectional view illustrating an embodiment taken along line IV-IV′ shown in FIG. 7. FIG. 9 is a schematic sectional view illustrating an embodiment taken along line V-V′ shown in FIG. 7.

Referring to FIGS. 7 to 9, the second manifold MF2 may include second holes H2 and a second air injection holes AIH2.

The second holes H2 may include a (2_a)th sub-hole H2_a, a (2_b)th sub-hole H2_b, a (2_c)th sub-hole H2_c, and a (2_d)th sub-hole H2_d. The (2_a)th to (2_d)th may be arranged along the first direction DR1.

The second holes H2 may be respectively connected to the first holes H1 in case that the first manifold MF1 is driven in the docking mode.

The second air injection holes AIH2 may be spaced apart from the second holes H2 in the third direction DR3, and be arranged side by side along the first direction DR1, like the second holes H2.

In embodiments, a number of the second holes H2 and a number of the second air injection holes AIH2 may be equal to each other. In the drawings, it is described that four second holes H2 and four second air injection holes AIH2 are formed. However, embodiments are not limited thereto. The number of the second holes H2 and the number of the second air injection holes AIH2 may be equal to the number of the first holes H1 formed in the first manifold MF1 and the number of the adsorption paths AT formed in the adsorption plate AP.

The second air injection holes AIH2 may be respectively connected to the first air injection holes AIH1 in case that the first manifold MF1 is driven in the docking mode.

FIG. 8 illustrates an embodiment of the second manifold MF2, taken along the line IV-IV′ shown in FIG. 7, and simultaneously illustrates the first to fourth adsorption paths AT1 to AT4 connected to the second holes H2.

Referring to FIG. 8, the adsorption paths AT may be connected to the second holes H2. In embodiments, an inlet H2_ai of the (2_a)th sub-hole H2_a may be connected to the first adsorption path AT1. An inlet H2_bi of the (2_b)th sub-hole H2_b may be connected to the second adsorption path AT2. An inlet H2_ci of the (2_c)th sub-hole H2_c may be connected to the third adsorption path AT3. An inlet H2_di of the (2_d)th sub-hole H2_d may be connected to the fourth adsorption path AT4. The number of the second holes H2 and the number of the adsorption paths AT may be equal to each other.

The second manifold MF2 may further include an impact absorbing member SAP surrounding a circumference of each of the second holes H2 on a surface of the second manifold MF2, which faces the first manifold MF1. The impact absorbing member SAP may be a component which is contracted in case that an external force is applied, and is restored to the original state, and may be made of a material having selected elasticity. For example, the impact absorbing member SAP may include elastic materials such as silicon, natural rubber, and elastic rubber.

Referring to FIG. 9, the second manifold MF2 may include second air injection holes AIH2. A number of the second air injection holes AIH2 may be equal to the number of the second holes H2. Each of the second air injection holes AIH2 may be connected to each of the first air injection holes AIH1 of the first manifold MF1, which corresponds to each of the second air injection holes AIH2.

The second manifold MF2 may further include an impact absorbing member SAP surrounding a circumference of each of the second air injection holes AIH2 on the surface of the second manifold MF2, which faces the first manifold MF1. For example, the impact absorbing member SAP may surround the second holes H2 and the second air injection holes AIH2, but embodiments are not limited thereto. For example, the impact absorbing member SAP may also be formed in the first manifold MF1. In other embodiments, the first manifold MF1 may further include an impact absorbing member SAP surrounding a circumference of each of the first holes H1 and the first air injection holes AIH1.

FIG. 10 is a schematic sectional view illustrating embodiments taken along line A-A′ shown in FIG. 4 and line B-B′ shown in FIG. 7 in case that the first manifold and the second manifold are in contact with each other.

In FIG. 10, only the (1_d)th sub-hole H1_d and the (2_d)th sub-hole H2_d among the (1_a)th to (1_d)th sub-holes H1_a to H1_d and the (2_a)th to (2_d)th sub-holes H2_a to H2_d are illustrated. However, the (1_a)th to (1_c)th sub-holes H1_a to H1_c and the (2_a)th to (2_c)th sub-holes H2_a to H2_c may be configured (formed) identically to the (1_d)th sub-hole H1_d and the (2_d)th sub-hole H2_d, and therefore, redundant descriptions will be omitted.

Referring to FIG. 10, in case that the first manifold MF1 is driven in the docking mode, the first manifold MF1 may be docked to the second manifold MF2 while approaching the second manifold MF2. In order for the first manifold MF1 to enter into the docking mode as described above, the carrier CR may temporarily suspend movement in the first direction and the opposite direction DR1. While the carrier CR moves in the first direction and the opposite direction DR1 to transfer the display panel DP, the carrier CR may be temporarily stopped at a position at which the first and second manifolds MF1 and MF2 overlap each other in the second direction DR2 so as to allow the display panel DP to be adsorbed to the adsorption plate AP.

For example, in a state in which the movement of the carrier CR is suspended, the first manifold MF1 may enter (or transition) into the docking mode, to be docked to the second manifold MF2 while approaching the second manifold MF2 in a direction facing the second manifold MF2.

In case that the first and second manifolds MF1 and MF2 are docked together as described above, the (1_d)th sub-hole H1_d and the (2_d)th sub-hole H2_d may be connected to each other. For example, in case that the first and second manifolds MF1 and MF2 are docked together, the (1_a)th sub-hole H1_a may be connected to the (2_a)th sub-hole H2_a, the (1_b)th sub-hole H1_b may be connected to the (2_b)th sub-hole H2_b, and the (1_c)th sub-hole H1_c may be connected to the (2_c)th sub-hole H2_c.

For example, in case that the first and second manifolds MF1 and MF2 are docked together, the first air injection hole AIH1 and the second air injection hole AIH2 may also be connected to each other.

In embodiments, at a surface at which the inlet H1_di of the (1_d)th sub-hole H1_d and the outlet H2_do of the (2_d)th sub-hole H2_d meet each other, the impact absorbing member SAP may be contracted between the first and second manifolds MF1 and MF2, so that the (1_d)th sub-hole H1_d and the (2_d)th sub-hole H2_d may be sealed therebetween. Air flowing from the (2_d)th hole H2_d to the (1_d)th sub-hole H1_d may not be leaked between the first and second manifolds MF1 and MF2.

For example, at a surface at which the outlet AIH1_o of the first air injection hole AIH1 and an inlet AIH2_i of the second air injection hole AIH2 meet each other, the impact absorbing member SAP may be contracted between the first and second manifolds MF1 and MF2, so that the first and second air injection holes AIH1 and AIH2 may be sealed therebetween. Air flowing from the first air injection hole AIH1 to the second air injection hole AIH2 may not be leaked between the first and second manifolds MF1 and MF2.

Although will be described later, that the first manifold MF1 is driven in the docking mode is for the purpose of separating the display panel DP from the adsorption plate AP by adsorbing the display panel DP to the adsorption plate AP as a space between the display panel DP and the adsorption plate AP is changed to the vacuum state or by releasing the vacuum state. For example, that the first manifold MF1 is driven in the docking mode is not a one-time work but a repetitive work. In a process in which the first manifold MF1 is in contact with the second manifold MF2 while approaching the second manifold MF2, a selected impact may occur between the first and second manifolds MF1 and MF2, and a fatigue failure may occur in case that the impact is continuously accumulated. The impact absorbing member SAP may immediately absorb an impact inevitably occurring between the first and second manifolds MF1 and MF2, so that the entire durability and reliability of the apparatus 10 may be improved. Further, the fatigue failure may be prevented.

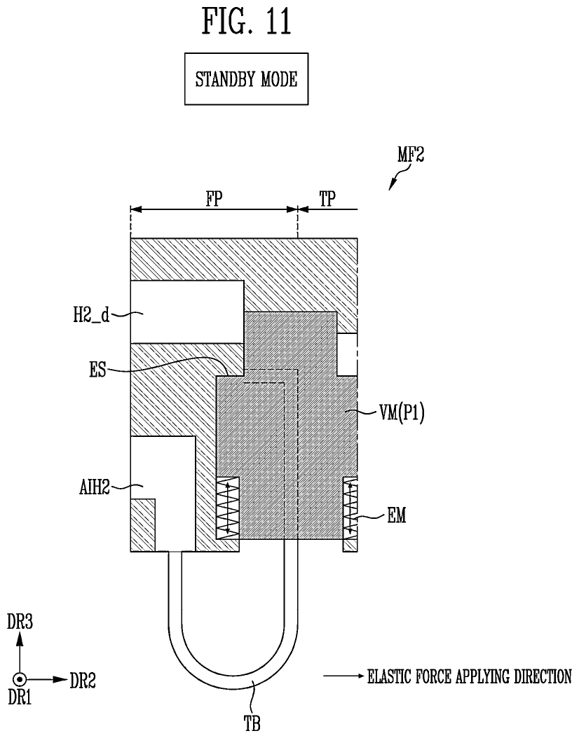

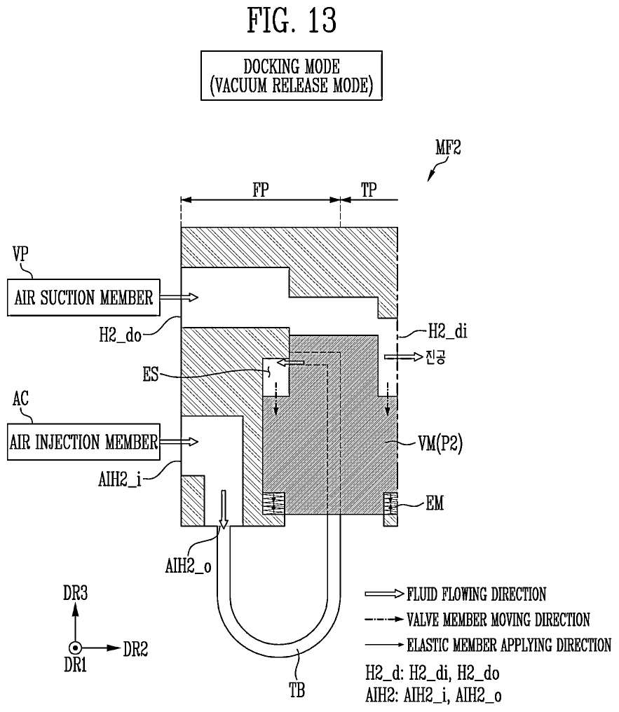

Hereinafter, operation examples of the standby mode and the docking mode of the apparatus 10 will be described with reference to FIGS. 11 and 13.

FIG. 11 is a schematic view illustrating an embodiment of the second manifold in case that the first manifold is in the standby mode.

An internal configuration of the second manifold MF2 will be additionally described with reference to FIG. 11. As shown in FIG. 11, the second manifold MF2 may further include a valve member VM, an elastic member EM, and a tube TB.

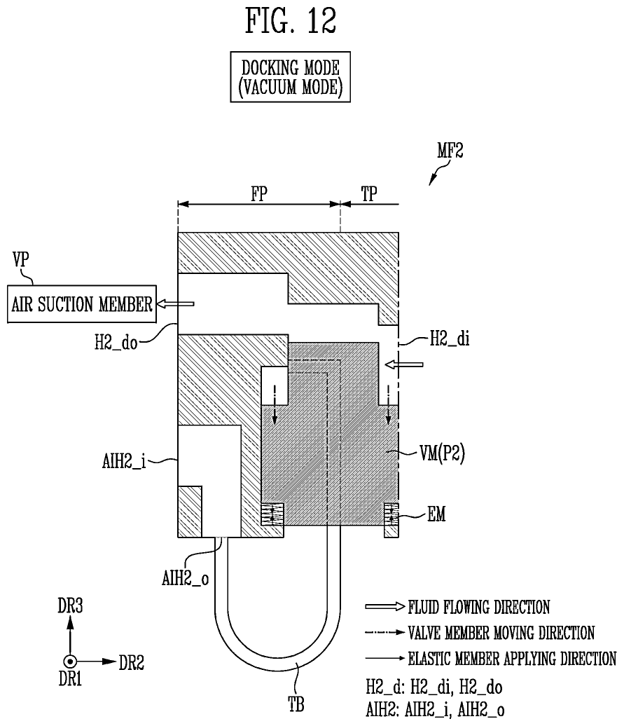

The valve member VM may be movable between a first position P1 at which the valve member VM interrupts a flow of air into any one of the second holes H2 and a second position (see P2 shown in FIGS. 12 and 13) at which the valve member VM allows a flow of air into any one of the second holes H2.

The elastic member EM may be disposed between an inner surface of the second manifold MF2 and the valve member VM to provide a selected elastic force to the valve member VM. In embodiments, the elastic member EM may include a compression spring. An end portion of the elastic member EM may be in a state in which the end is fixed to the inner surface of the second manifold MF2, and another end portion of the elastic member EM may apply, to the valve member VM, a force pushing the valve member VM in the third direction DR3. The valve member VM may move to the first position P1 by the elastic force of the elastic member EM, and maintain the first position P1.

An end portion of the tube TB may be connected to any one of the second air injection holes AIH2, and another end portion of the tube TB may be connected to an empty space ES between the second manifold MF2 and the valve member VM.

As described above, FIG. 11 illustrates a state in which the first manifold MF1 is driven in the standby mode, and the air suction member VP does not operate. FIG. 11 illustrates a state in which the display panel DP has already been adsorbed on the adsorption plate AP by performing the docking mode which will be described below with reference to FIG. 12. For example, in a state in which the carrier CR supports the adsorption plate AP and the adsorption plate AP adsorbs the display panel DP, the carrier CR may move in the first direction DR1 and the opposite direction of the first direction DR1. Accordingly, the carrier CR may transfer the display panel in the first direction DR1 and the opposite direction of the first direction DR1 in a state in which the display panel DP is fixed to the adsorption plate AP.

Hereinafter, for convenience of description, a portion of the second manifold MF2, which is adjacent to a side of the first manifold MF1 with respect to the center portion of the valve member VM, is referred to as a front-end portion FP, and another portion of the second manifold MF2, which is adjacent to the adsorption plate AP with respect to the center portion of the valve member VM, is referred to as a rear end portion TP.

While the carrier CR moves in the standby mode as shown in FIG. 11, the valve member VM may adopt a posture in which the first position P1 is maintained by the elastic force of the elastic member EM. As described above, since a state between the adsorption plate AP and the display panel DP is the vacuum state, the rear end portion TP of the (2_d)th sub-hole H2_d may also be in a vacuum condition. Since the front-end portion FP of the (2_d)th sub-hole H2_d is connected to the air suction member VP, the front-end portion FP of the (2_d)th sub-hole H2_d may be in the vacuum condition or a state having a pressure slightly higher than vacuum. Any flow of air (or airflow) may not exist inside the (2_d)th sub-hole H2_d, or a flow of air may be induced from the (1_d)th sub-hole H1_d to the (2_d)th sub-hole H2_d. In such a condition, the valve member VM may move to the first position P1 by the elastic force with which the elastic member EM pressurizes the valve member VM, and maintain such a posture. Since the pressure of air induced from the (1_d)th sub-hole H1_d to the (2_d)th sub-hole H2_d is smaller than the elastic force with which the elastic member EM pressurizes the valve member VM, the valve member VM may not move in a direction opposite to the third direction DR3 but may be fixed at the first position P1, to interrupt a flow of air in a direction facing the (2_d)th sub-hole H2_d from the (1_d)th sub-hole H1_d.

According to an embodiment, the state between the display panel DP and the adsorption plate AP may be maintained as the vacuum state, not using electricity but using only air pressure. Accordingly, the carrier CR may move in a state in which the display panel DP is stably adsorbed to the adsorption plate AP, so that the display panel DP may be transferred.

FIG. 12 is a schematic view illustrating an operation example of the second manifold in case that the first manifold is driven in the docking mode.

Referring to FIG. 12, as the first manifold MF1 is driven in the docking mode, the first and second manifolds MF1 and MF2 may be in contact with each other, and the air suction member VP may operate in this state. In case that the air suction member VP operates in the state in which the first manifold MF1 is driven in the docking mode as described above, the display panel DP may be adsorbed on the adsorption plate AP. That the display panel DP is adsorbed on the adsorption plate AP may be implemented by changing the space between the display panel DP and the adsorption plate AP to the vacuum state, using the air suction member VP. On this account, this is referred to as a “vacuum mode” in the drawing.

The state in which the first and second manifolds MF1 and MF2 are in contact with each other will quote FIG. 10. For convenience of description, illustration of the first manifold MF1 will be omitted in FIG. 12.

In case that the air suction member VP operates, a flow of air from the inlet H2_di of the (2_d)th sub-hole H2_d to the outlet H2_do of the (2_d)th sub-hole H2_d may occur. This will be described in detail as follows.

In case that the air suction member VP starts operating, a pressure of the front-end portion FP of the (2_d)th sub-hole H2_d may instantaneously become lower than a pressure of the rear end portion TP of the (2_d)th sub-hole H2_d. Accordingly, a flow of air may occur through a minute gap between the valve member VM and the second manifold MF2. Since the air suction member VP continuously operates in this state, an amount of air flowing from the inlet H2_di of the (2_d)th sub-hole H2_d to the outlet H2_do of the (2_d)th sub-hole H2_d may be gradually increased. After that, at any time point, an air pressure of air flowing from the inlet H2_di of the (2_d)th sub-hole H2_d to the outlet H2_do of the (2_d)th sub-hole H2_d may become higher than an elastic force with which the elastic member EM pressurizes the valve member VM in the third direction DR3. In case that the air pressure of air flowing from the inlet H2_di of the (2_d)th sub-hole H2_d to the outlet H2_do of the (2_d)th sub-hole H2_d becomes higher than the elastic force of the elastic member EM, the valve member VM may move to the second position P2.

In case that the air suction member VP continuously operates in the state in which the valve member VM moves to the second position P2 as described above, air existing in the space between the display panel DP and the adsorption plate AP may be continuously sucked through the fourth adsorption hole (e.g., AH4 shown in FIG. 2), and the air sucked through the fourth adsorption hole AH4 may be sucked into the air suction member sequentially via the fourth adsorption path (e.g., AT4 shown in FIG. 8), the (2_d)th sub-hole H2_d, and the (1_d)th sub-hole H1_d.

As described above, a flow of air from the inlet (e.g., H2_ai shown in FIG. 8) of the (2_a)th sub-hole (e.g., H2_a shown in FIG. 8) to an outlet (e.g., H2_ao shown in FIG. 8) of the (2_a)th sub-hole H2_a may occur in case that the air suction member VP operates. By the same principle as the principle described above, in case that the air suction member VP operates, air may starts being sucked through the first adsorption hole (e.g., AH1 shown in FIG. 2), and the air sucked through the first adsorption hole AH1 may be sucked into the air suction member VP sequentially via the first adsorption path (e.g., AT1 shown in FIG. 8), the (2_a)th sub-hole H2_a, and the (1_a)th sub-hole H1_a.

In case that the air suction member VP operates, a flow of air from the inlet (e.g., H2_bi shown in FIG. 8) of the (2_b)th sub-hole (e.g., H2_b shown in FIG. 8) to an outlet (e.g., H2_bo shown in FIG. 8) of the (2_b)th sub-hole (e.g., H2_b shown in FIG. 8) may occur. By the same principle as the principle described above, in case that the air suction member VP operates, air may start being sucked through the second adsorption hole (e.g., AH2 shown in FIG. 2), and the air sucked through the second adsorption hole AH2 may be sucked into the air suction member VP sequentially via the second adsorption path (e.g., AT2 shown in FIG. 8), the (2_b)th sub-hole H2_b, and the (1_b)th sub-hole H1_b.

In case that the air suction member VP operates, a flow of air from the inlet (e.g., H2_ci shown in FIG. 8) of the (2_c)th sub-hole (e.g., H2_c shown in FIG. 8) to an outlet (e.g., H2_co shown in FIG. 8) of the (2_c)th sub-hole (e.g., H2_c shown in FIG. 8) may occur. By the same principle as the principle described above, in case that the air suction member VP operates, air may start being sucked through the third adsorption hole (e.g., AH3 shown in FIG. 2), and the air sucked through the third adsorption hole AH3 may be sucked into the air suction member VP sequentially via the first adsorption path (e.g., AT3 shown in FIG. 8), the (2_c)th sub-hole (e.g., H2_c), and the (1_c)th sub-hole H1_c.

For example, in case that the air suction member VP operates in the state in which the first and second manifolds MF1 and MF2 are docked together, the valve member VM may move to the second position P2, thereby opening flow paths of the second holes H2. Therefore, air existing in a space between the first to fourth adsorption holes AH1 to AH4 and the display panel DP may be sucked into the air suction member VP. Accordingly, the space between the display panel DP and the adsorption plate AP may be induced to the vacuum condition, and thus the display panel DP may be adsorbed on the adsorption plate AP.

For example, as described with reference to FIG. 5, the air suction member VP may include first to fourth air suction members VP1 to VP4, and individually (or independently) operate at least one of the first to fourth air suction members VP1 to VP4. This may be for the purpose of selectively sucking air at the periphery of the first to fourth adsorption holes AH1 to AH4 required to adsorb the display panel DP by considering a size of the display panel DP.

For example, in case that the display panel DP is a large-sized panel having a size with which the display panel overlaps all the first to fourth adsorption holes AH1 to AH4, a space between the display panel DP and the adsorption plate AP, which corresponds to an area occupied by the first to fourth adsorption holes AH1 to AH4, may be changed to the vacuum state by operating all the first to fourth air suction members VP1 to VP4. In another example, in case that the display panel DP is a small-sized panel having a size with which the display panel overlaps only the first adsorption holes AH1 and does not overlap the second to fourth adsorption holes AH2 to AH4, only a space between the display panel DP and the adsorption plate AP, which corresponds to an area occupied by the first adsorption holes AH1, may be changed to the vacuum state by operating only the first air suction member VP1. In case that the first to fourth air suction members VP1 to VP4 are individually (or independently) operated by considering the size of the display panel DP as described above, unnecessary driving may be omitted, and thus power consumption may be saved.

After the display panel DP is adsorbed on the adsorption plate AP, driving of the air suction member VP may be suspended. In case that the driving of the air suction member VP is suspended, the space between the display panel DP and the adsorption plate AP may be induced to the vacuum state. For example, the vacuum state may be maintained for a selected time even after the driving of the air suction member VP is suspended. Accordingly, the space between the display panel DP and the adsorption plate AP and the air suction member VP may substantially maintain a state having the same pressure for the selected time after the driving of the air suction member VP is suspended. Therefore, no flow of air may occur inside the (2_d)th sub-hole H2_d. In case that no flow of air exists inside the (2_d)th sub-hole H2_d as described above, the valve member VM may be restored to the first position P1 as shown in FIG. 11 by the elastic force with which the elastic member EM pressurizes the valve member VM in the third direction DR3.

According to this operation, as the valve member VM moves to the first position P1, thereby mechanically interrupting a flow path of the second hole H2 without supplying separate power to maintain the space between the display panel DP and the adsorption plate AP to be in the vacuum state, the space between the display panel DP and the adsorption plate AP may continuously maintain the vacuum state, and accordingly, the display panel DP may be stably adsorbed on the adsorption plate AP. In this state, the carrier CR moves in the first direction DR1 and the opposite direction of the first direction DR1 as described with reference to FIG. 11, so that the display panel DP may be transferred.

FIG. 13 is a schematic view illustrating another operation example of the second manifold in case that the first manifold is driven in the docking mode.

FIG. 13 is a schematic view illustrating a “vacuum release mode” which may be performed in a state in which the display panel DP is adsorbed on the adsorption plate AP after the vacuum mode shown in FIG. 12 is performed.

After the “vacuum mode” shown in FIG. 12 is performed, the display panel DP may be transferred in a state in which the display panel DP is mechanically adsorbed on the adsorption plate AP without supplying separate power. After that, at any time point, the vacuum release mode shown in FIG. 13 may be performed in case that it is necessary for the display panel DP to be separated from the adsorption plate AP.

Referring to FIG. 13, as the first manifold MF1 is driven in the docking mode, the first and second manifolds MF1 and MF2 may be in contact with each other, and the air injection member AC may operate in this state. In case that the air injection member AC operates in the state in which the first manifold MF1 is driven in the docking mode as described above, air may be injected into the space between the display panel DP and the adsorption plate AP, thereby may celling the vacuum state.

Like FIG. 12, the state in which the first and second manifolds MF1 and MF2 are in contact with each other will quote FIG. 10. For convenience of description, illustration of the first manifold MF1 will be omitted in FIG. 13.

In case that the air injection member AC operates, a flow of air from the inlet AIH2_i of the second air injection hole AIH2 to an outlet AIH2_o of the second air injection hole AIH2 may occur. This will be described in detail as follows.

In case that the air injection member AC starts operating, air injected into the second air injection hole AIH2 may be introduced (or flowed) into the empty space ES between the valve member VM located at the front-end portion of the second manifold MF2 and the second manifold MF2 while moving along the tube TB. The air introduced (or flowed) into the empty space ES between the valve member VM and the second manifold MF2 as described above may apply, to the valve member VM, a force pushing the valve member VM in the direction opposite to the third direction DR3. The air introduced (or flowed) into the empty space ES may move in the direction (i.e., a lower direction) opposite to the third direction DR3 from a moment at which an air pressure applied to the empty space ES becomes higher than an elastic force with which the elastic member EM pushes the valve member VM in the third direction DR3, and finally move up to the second position P2 at which the (2_d)th sub-hole H2_d is opened.

In case that the valve member VM moves to the second position P2 as described above, a flow of air in a direction (the second direction DR2 in FIG. 13) facing the fourth adsorption hole H4 from the air suction member VP having a relatively high atmospheric pressure may occur. Accordingly, air may be introduced (or flowed) from the air suction member VP to the (1_d)th sub-hole H1_d, and the air introduced (or flowed) into the (1_d)th sub-hole H1_d may be injected into the space between the display panel DP and the adsorption plate AP sequentially via the (2_d)th sub-hole H2_d, the fourth adsorption path (e.g., AT4 shown in FIG. 8), and the fourth adsorption hole (e.g., AH4 shown in FIG. 2).

For this driving, the air suction member VP may be standing by in a state in which the vacuum state is not maintained any more after the vacuum mode is performed. In the vacuum release mode, the air suction member VP may be in a state in which the air suction member VP has an internal pressure relatively higher than the vacuum state.

In the air injection member AC operates, a flow of air from the outlet (e.g., H2_ao shown in FIG. 8) of the (2_a)th sub-hole (e.g., H2_a shown in FIG. 8) to the inlet H2_ai of the (2_a)th sub-hole H2_a may occur. By the same principle as the principle described above, in case that the air injection member AC operates, air may start being introduced (or flowed) through the (1_a)th sub-hole H1_a as the valve member VM moves to the second position P2, and the air introduced (or flowed) into the (1_a)th sub-hole H1_a may be introduced (or flowed) to the space between the display panel DP and the adsorption plate AP sequentially via the (2_a)th sub-hole H2_a, the first adsorption path (e.g., AT1 shown in FIG. 8), and the first adsorption hole AH1.

In case that the air injection member AC operates, a flow of air from the outlet (e.g., H2_bo shown in FIG. 8) of the (2_b)th sub-hole (e.g., H2_b shown in FIG. 8) to the inlet H2_bi of the (2_b)th sub-hole H2_b may occur. By the same principle as the principle described above, in case that the air injection member AC operates, air may start being introduced (or flowed) through the (1_b)th sub-hole H1_b as the valve member VM moves to the second position P2, and the air introduced (or flowed) into the (1_b)th sub-hole H1_b may be introduced (or flowed) to the space between the display panel DP and the adsorption plate AP sequentially via the (2_b)th sub-hole H2_b, the second adsorption path (e.g., AT2 shown in FIG. 8), and the second adsorption hole AH2.

In case that the air injection member AC operates, a flow of air from the outlet (e.g., H2_co shown in FIG. 8) of the (2_c)th sub-hole (e.g., H2_c shown in FIG. 8) to the inlet H2_ci of the (2_c)th sub-hole H2_c may occur. By the same principle as the principle described above, in case that the air injection member AC operates, air may start being introduced (or flowed) through the (1_c)th sub-hole H1_c as the valve member VM moves to the second position P2, and the air introduced (or flowed) into the (1_c)th sub-hole H1_c may be introduced (or flowed) to the space between the display panel DP and the adsorption plate AP sequentially via the (2_c)th sub-hole H2_c, the third adsorption path (e.g., AT3 shown in FIG. 8), and the third adsorption hole AH3. For example, in case that the air injection member AC operates in the state in which the first and second manifolds MF1 and MF2 are docked together, the valve member VM may move to the second position P2, thereby opening a flow path of the second hole H2. Therefore, air may be supplied a space between the first to fourth adsorption holes AH1 to AH4 and the display panel DP. Accordingly, the state in which the display panel DP is adsorbed on the adsorption plate AP may be cancelled.

For example, like the air suction member VP, the air injection member AC may include air injection members to respectively correspond one-to-one to the second air injection holes AIH2 and inject airs into each of the second air injection holes AIH2. Accordingly, the air injection members AC may individually (or independently) operate such that air may be supplied to an area required to destroy the vacuum state among the first to fourth adsorption holes AH1 to AH4. In case that the air injection members AC individually (or independently) operate by considering the size of the display panel DP as described above, unnecessary driving may be omitted, and thus power consumption may be saved.

In the apparatus in accordance with the invention, a display panel may be stably transferred in a state in which the display panel is vacuum-adsorbed using only an air pressure without using electricity.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. An apparatus for transferring a display panel, the apparatus comprising:
a frame;
a carrier disposed on the frame to be movable in a first direction and an opposite direction of the first direction;
an adsorption plate disposed on the carrier to support the display panel;
a first manifold including a plurality of first holes, the first manifold being formed at the frame to be movable in a second direction intersecting the first direction and an opposite direction of the second direction; and
a second manifold including a plurality of second holes, the second manifold being formed at the adsorption plate to face the first manifold, wherein
the first manifold is driven in a docking mode and a standby mode,
in the docking mode, the first manifold is in contact with the second manifold such that the plurality of first holes are connected to the plurality of second holes, and
in the standby mode, the first manifold is spaced apart from the second manifold such that the plurality of first holes are separated from the plurality of second holes.

2. The apparatus of claim 1, wherein the adsorption plate incudes:
a plurality of adsorption holes connected to the plurality of second holes; and
a plurality of adsorption paths connecting the plurality of adsorption holes to each other.

3. The apparatus of claim 2, wherein
the plurality of adsorption holes include:
a plurality of first adsorption holes adjacent to a center portion of the adsorption plate; and
a plurality of second adsorption holes spaced farther from the center portion of the adsorption plate than the plurality of first adsorption holes, and each adsorption path includes:
a first adsorption path connecting the plurality of first adsorption holes to each other; and
a second adsorption path connecting the plurality of second adsorption holes to each other.

4. The apparatus of claim 3, wherein
the first adsorption path is connected to one of the plurality of second holes, and
the second adsorption path is connected to another one of the plurality of second holes.

5. The apparatus of claim 3, wherein at least one of the first and second adsorption paths has an open-loop shape.

6. The apparatus of claim 2, wherein the plurality of adsorption holes penetrate the adsorption plate in a third direction intersecting the first and second directions.

7. The apparatus of claim 6, further comprising:
at least one vacuum chamber formed at a surface of the adsorption plate, which is not in contact with the display panel, the at least one vacuum chamber being connected to some of the plurality of adsorption holes.

8. The apparatus of claim 1, further comprising:
an air suction member connected to the plurality of first holes and the plurality of second holes to suck air between the display panel and the adsorption plate in case that the first manifold is driven in the docking mode.

9. The apparatus of claim 1, wherein
the first manifold further includes a plurality of first air injection holes,
the second manifold further includes a plurality of second air injection holes, and
in case that the first manifold is driven in the docking mode, the plurality of first air injection holes are connected to the plurality of second air injection holes, respectively.

10. The apparatus of claim 9, wherein
a number of the plurality of first holes and a number of the plurality of first air injection holes are equal to each other, and
a number of the plurality of second holes and a number of the plurality of second air injection holes are equal to each other.

11. The apparatus of claim 9, wherein
at least one of the first manifold and the second manifold further includes an impact absorbing member surrounding a circumference of each of the plurality of first air injection holes or the plurality of second air injection holes disposed on a surface at which the first manifold and the second manifold face each other, and
in case that the first manifold is driven in the docking mode, the impact absorbing member seals one of the plurality of first holes and one of the plurality of second holes, which are connected to each other.

12. The apparatus of claim 9, further comprising:
an air injection member connected to one of the plurality of first air injection holes and one of the plurality of second air injection holes, which are connected to each other, to inject air into the second manifold in case that the first manifold is driven in the docking mode.

13. The apparatus of claim 9, wherein the second manifold further includes:
a valve member movable between a first position at which the valve member interrupts a flow of air into one of the plurality of second holes and a second position at which the value member allows a flow of air into one of the plurality of second holes;
an elastic member disposed between an inner surface of the second manifold and the valve member to provide an elastic force to the valve member; and
a tube having an end portion connected to one of the plurality of second air injection holes and another end portion connected to an empty space between the second manifold and the valve member.

14. The apparatus of claim 13, wherein, in case that a flow of air does not exist or in case that a flow of air from one of the plurality of first holes to one of the plurality of second holes occurs, the valve member moves to the first position by the elastic force with which the elastic member pressurizes the valve member.

15. The apparatus of claim 13, wherein, in case that a flow of air from one of the plurality of second holes to one of the plurality of first holes occurs, the valve member moves to the second position by an air pressure that is higher than the elastic force.

16. The apparatus of claim 15, wherein, in case that the valve member moves to the second position, the adsorption plate adsorbs the display panel by inducing a vacuum condition in a space between the display panel and the adsorption plate.

17. The apparatus of claim 13, wherein in case that air is introduced into one of the plurality of second air injection holes, the air introduced into the one of the plurality of second air injection holes is induced to the empty space between the second manifold and the valve member while moving along the tube, and the valve member moves to the second position by air pressure applied to the empty space between the second manifold and the valve member and being higher than the elastic force.

18. The apparatus of claim 17, wherein, in case that the valve member moves to the second position, an adsorption condition of the display panel and the adsorption plate is cancelled by the air supplied to a space between the display panel and the adsorption plate.

19. The apparatus of claim 1, wherein at least one of the first manifold and the second manifold further includes an impact absorbing member surrounding a circumference of each of the plurality of first holes or the plurality of second holes disposed on a surface at which the first manifold and the second manifold face each other, and in case that the first manifold is driven in the docking mode, the impact absorbing member seals one of the plurality of first holes and one of the plurality of second holes, which are connected to each other.

20. The apparatus of claim 1, further comprising:
a driving member formed at the first manifold to provide the first manifold with a driving force with which the first manifold moves in the second direction and the opposite direction of the second direction.
